(19) United States
(12) Patent Application Publication
(10) Pub. No.: US 2023/0268966 A1
(43) Pub. Date: Aug. 24, 2023

(54) BEAM STEERING DEPENDENT IMPEDANCE MATCHING OF ARRAY ANTENNAS

(71) Applicant: NOKIA TECHNOLOGIES OY, Espoo (FI)

(72) Inventors: Simon SVENDSEN, Aalborg (DK); Samantha CAPORAL DEL BARRIO, Aalborg (DK); Johannes HARREBEK, Aalborg (DK)

(73) Assignee: NOKIA TECHNOLOGIES OY, Espoo (FI)

(21) Appl. No.: 18/004,088

(22) PCT Filed: Jun. 24, 2021
(86) PCT No.: PCT/FI2021/050494

§ 371 Date: Jan. 3, 2023

(30) Foreign Application Priority Data
Jul. 3, 2020 (FI) 20205720

(51) Int. Cl. H04B 7/06; H01Q 3/36; H04B 7/08; H03H 11/28

(52) U.S. Cl. CPC H04B 7/0617; H01Q 3/36; H04B 7/086; H03H 11/28

(57) ABSTRACT

According to an aspect, there is provided a radio frequency front end (202) for a beamforming transceiver (201) having an antenna array comprising a plurality of antenna elements. The radio frequency front end comprises, for each antenna element, at least two radio frequency beamforming branches (218, 219). Each of at least one of said at least two radio frequency beamforming branches comprises an electrically tunable phase shifting element (221, 231), first and second transmission/reception switches (223, 233), a low-noise amplifier (225, 235) for reception and a power amplifier (224, 234) for transmission. Moreover, each of at least one of said at least two radio frequency beamforming branches comprises an electrically switchable matching circuit (226, 236). The electrically switchable matching circuit comprises two or more matching circuit settings selectable via switching. Each of the two or more matching circuit settings is configured for providing impedance matching for an antenna element at one or more beam steering angles in transmission.

### TECHNICAL FIELD

Various example embodiments relate to wireless communications.

### BACKGROUND

5G New Radio (NR) defines a beam alignment procedure between a terminal device (or user equipment, UE) and an access node (gNodeB, gNB) for obtaining a transmission beam of the access node and a reception beam of the terminal device which are defined so as to maximize directional gain and minimize interference on other users in serving and neighbor cells. Said beamforming procedure is based solely on downlink measurements. As a consequence, said beamforming procedure fails to guarantee that optimal alignment of the transmission beam (or uplink beam) of the terminal device will always be aligned with the access node when configured with the same array settings (phase and power) as used for downlink. One of the reasons for this discrepancy is that the frequency dependent (and thus also steering angle dependent) impedances seen by the individual elements of a phased array in transmission and reception may differ from each other considerably. Thus, there is a need for a beam alignment solution which would be able to provide optimal beams for both uplink and downlink in an efficient manner.

### BRIEF DESCRIPTION

According to an aspect, there is provided the subject matter of the independent claims. Embodiments are defined in the dependent claims. The scope of protection sought for various embodiments of the invention is set out by the independent claims.

The embodiments and features, if any, described in this specification that do not fall under the scope of the independent claims are to be interpreted as examples useful for understanding various embodiments of the invention.

### BRIEF DESCRIPTION OF DRAWINGS

In the following, example embodiments will be described in greater detail with reference to the attached drawings, in which

FIG. 1 illustrates an exemplary wireless communication system according to embodiments;

FIGS. 2A, 2B, 2C and 2D illustrate apparatuses according to embodiments or parts thereof;

FIG. 2E illustrates an operating principle of an apparatus according to an embodiment;

FIGS. 3A, 3B and 4 illustrate comparisons of results achieved with a conventional RF front end for beamforming and a RF front end according to embodiments;

FIGS. 5A and 5B illustrate apparatuses according to embodiments;

FIG. 6 illustrates a process according to embodiments; and

FIG. 7 illustrates an apparatus according to embodiments.

### DETAILED DESCRIPTION OF SOME EMBODIMENTS

The following embodiments are only presented as examples. Although the specification may refer to “an”, “one”, or “some” embodiment(s) and/or example(s) in several locations of the text, this does not necessarily mean that each reference is made to the same embodiment(s) or example(s), or that a particular feature only applies to a single embodiment and/or example. Single features of different embodiments and/or examples may also be combined to provide other embodiments and/or examples.

In the following, different exemplifying embodiments will be described using, as an example of an access architecture to which the embodiments may be applied, a radio access architecture based on long term evolution advanced (LTE Advanced, LTE-A) or new radio (NR, 5G), without restricting the embodiments to such an architecture, however. It is obvious for a person skilled in the art that the embodiments may also be applied to other kinds of communications networks having suitable means by adjusting parameters and procedures appropriately. Some examples of other options for suitable systems are the universal mobile telecommunications system (UMTS) radio access network (UTRAN or E-UTRAN), long term evolution (LTE, the same as E-UTRA), wireless local area network (WLAN or WiFi), worldwide interoperability for microwave access (WiMAX), Bluetooth®, personal communications services (PCS), ZigBee®, wideband code division multiple access (WCDMA), systems using ultra-wideband (UWB) technology, sensor networks, mobile ad-hoc networks (MANETs), Internet Protocol multimedia subsystems (IMS) and passive optical networks (PON) or any combination thereof.

Unless otherwise stated, the term “beam” as used in this application corresponds to the main beam (of an antenna array).

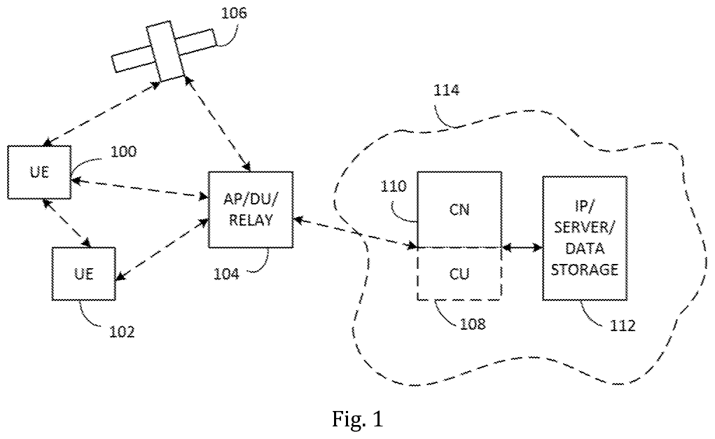

FIG. 1 depicts examples of simplified system architectures only showing some elements and functional entities, all being logical units, whose implementation may differ from what is shown. The connections shown in FIG. 1 are logical connections; the actual physical connections may be different. It is apparent to a person skilled in the art that the system typically comprises also other functions and structures than those shown in FIG. 1.

The embodiments are not, however, restricted to the system given as an example but a person skilled in the art may apply the solution to other communication systems provided with necessary properties.

The example of FIG. 1 shows a part of an exemplifying radio access network.

FIG. 1 shows user devices 100 and 102 configured to be in a wireless connection on one or more communication channels in a cell with an access node (such as (e/g)NodeB) 104 providing the cell (and possibly also one or more other cells). The cells may be equally called sectors, especially when multiple cells are associated with a single access node (e.g., in tri-sector or six-sector deployment). Each cell may define a coverage area or a service area of the access node. Each cell may be, for example, a macro cell or an indoor/outdoor small cell (a micro, femto, or a pico cell). The physical link from a user device to a (e/g)NodeB is called uplink or reverse link and the physical link from the (e/g)NodeB to the user device is called downlink or forward link. It should be appreciated that (e/g)NodeBs or their functionalities may be implemented by using any node, host, server or access point etc. entity suitable for such a usage.

A communications system typically comprises more than one (e/g)NodeB in which case the (e/g)NodeBs may also be configured to communicate with one another over links, wired or wireless, designed for the purpose. These links may be used for signaling purposes. The (e/g)NodeB is a computing device configured to control the radio resources of communication system it is coupled to. The NodeB may also be referred to as a base station, an access point or any other type of interfacing device including a relay station capable of operating in a wireless environment. The (e/g)NodeB includes or is coupled to transceivers. From the transceivers of the (e/g)NodeB, a connection is provided to an antenna unit that establishes bi-directional radio links to user devices. The antenna unit may comprise a plurality of antennas or antenna elements. The (e/g)NodeB is further connected to core network 110 (CN or next generation core NGC). Depending on the system, the counterpart on the CN side can be a serving gateway (S-GW, routing and forwarding user data packets), packet data network gateway (P-GW), for providing connectivity of user devices (UEs) to external packet data networks, or mobile management entity (MME), etc.

The user device (also called UE, user equipment, user terminal, terminal device, etc.) illustrates one type of an apparatus to which resources on the air interface are allocated and assigned, and thus any feature described herein with a user device may be implemented with a corresponding apparatus, such as a relay node. An example of such a relay node is a layer 3 relay (self-backhauling relay) towards the base station.

The user device typically refers to a portable computing device that includes wireless mobile communication devices operating with or without a subscriber identification module (SIM), including, but not limited to, the following types of devices: a mobile station (mobile phone), smartphone, personal digital assistant (PDA), handset, device using a wireless modem (alarm or measurement device, etc.), laptop and/or touch screen computer, tablet, game console, notebook, and multimedia device. Each user device may comprise one or more antennas. It should be appreciated that a user device may also be a nearly exclusive uplink only device, of which an example is a camera or video camera loading images or video clips to a network. A user device may also be a device having capability to operate in (Industrial) Internet of Things ((I)IoT) network which is a scenario in which objects are provided with the ability to transfer data over a network without requiring human-to-human or human-to-computer interaction. The user device (or in some embodiments a layer 3 relay node) is configured to perform one or more of user equipment functionalities. The user device may also be called a subscriber unit, mobile station, remote terminal, access terminal, user terminal or user equipment (UE) just to mention but a few names or apparatuses.

Various techniques described herein may also be applied to a cyber-physical system (CPS) (a system of collaborating computational elements controlling physical entities). CPS may enable the implementation and exploitation of massive amounts of interconnected ICT devices (sensors, actuators, processors microcontrollers, etc.) embedded in physical objects at different locations. Mobile cyber physical systems, in which the physical system in question has inherent mobility, are a subcategory of cyber-physical systems. Examples of mobile physical systems include mobile robotics and electronics transported by humans or animals.

Additionally, although the apparatuses have been depicted as single entities, different units, processors and/or memory units (not all shown in FIG. 1) may be implemented.

5G enables using (massive) multiple input-multiple output ((m)MIMO) antennas (each of which may comprise multiple antenna elements), many more base stations or nodes than the LTE (a so-called small cell concept), including macro sites operating in co-operation with smaller stations and employing a variety of radio technologies depending on service needs, use cases and/or spectrum available. A MIMO antenna (comprising a plurality of antenna elements) may be equally called a MIMO array antenna, a MIMO antenna array or a MIMO phased array (comprising a plurality of antennas or antenna elements). 5G mobile communications supports a wide range of use cases and related applications including video streaming, augmented reality, different ways of data sharing and various forms of machine type applications, including vehicular safety, different sensors and real-time control. 5G is expected to have multiple radio interfaces, namely below 6 GHz, cmWave and mmWave, and also being integratable with existing legacy radio access technologies, such as the LTE. Integration with the LTE may be implemented, at least in the early phase, as a system, where macro coverage is provided by the LTE and 5G radio interface access comes from small cells by aggregation to the LTE. In other words, 5G is planned to support both inter-RAT operability (such as LTE-5G) and inter-RI operability (inter-radio interface operability, such as below 6 GHz-cmWave, below 6 GHz-cmWave-mmWave). One of the concepts considered to be used in 5G networks is network slicing in which multiple independent and dedicated virtual sub-networks (network instances) may be created within the same infrastructure to run services that have different requirements on latency, reliability, throughput and mobility.

The current architecture in LTE networks is fully distributed in the radio and fully centralized in the core network. The low latency applications and services in 5G require to bring the content close to the radio which leads to local break out and multi-access edge computing (MEC). 5G enables analytics and knowledge generation to occur at the source of the data. This approach requires leveraging resources that may not be continuously connected to a network such as laptops, smartphones, tablets and sensors. MEC provides a distributed computing environment for application and service hosting. It also has the ability to store and process content in close proximity to cellular subscribers for faster response time. Edge computing covers a wide range of technologies such as wireless sensor networks, mobile data acquisition, mobile signature analysis, cooperative distributed peer-to-peer ad hoc networking and processing also classifiable as local cloud/fog computing and grid/mesh computing, dew computing, mobile edge computing, cloudlet, distributed data storage and retrieval, autonomic self-healing networks, remote cloud services, augmented and virtual reality, data caching, Internet of Things (massive connectivity and/or latency critical), critical communications (autonomous vehicles, traffic safety, real-time analytics, time-critical control, healthcare applications).

The communication system is also able to communicate with other networks, such as a public switched telephone network or the Internet 112, or utilize services provided by them. The communication network may also be able to support the usage of cloud services, for example at least part of core network operations may be carried out as a cloud service (this is depicted in FIG. 1 by “cloud” 114). The communication system may also comprise a central control entity, or a like, providing facilities for networks of different operators to cooperate for example in spectrum sharing.

Edge cloud may be brought into radio access network (RAN) by utilizing network function virtualization (NVF) and software defined networking (SDN). Using edge cloud may mean access node operations to be carried out, at least partly, in a server, host or node operationally coupled to a remote radio head or base station comprising radio parts. It is also possible that node operations will be distributed among a plurality of servers, nodes or hosts. Application of cloudRAN architecture enables RAN real time functions being carried out at the RAN side (in a distributed unit, DU 104) and non-real time functions being carried out in a centralized manner (in a centralized unit, CU 108).

It should also be understood that the distribution of labor between core network operations and base station operations may differ from that of the LTE or even be non-existent. Some other technology advancements probably to be used are Big Data and all-IP, which may change the way networks are being constructed and managed. 5G (or new radio, NR) networks are being designed to support multiple hierarchies, where MEC servers can be placed between the core and the base station or nodeB (gNB). It should be appreciated that MEC can be applied in 4G networks as well.

5G may also utilize satellite communication to enhance or complement the coverage of 5G service, for example by providing backhauling. Possible use cases are providing service continuity for machine-to-machine (M2M) or Internet of Things (IoT) devices or for passengers on board of vehicles, or ensuring service availability for critical communications, and future railway/maritime/aeronautical communications. Satellite communication may utilize geostationary earth orbit (GEO) satellite systems, but also low earth orbit (LEO) satellite systems, in particular mega-constellations (systems in which hundreds of (nano)satellites are deployed). Each satellite 106 in the mega-constellation may cover several satellite-enabled network entities that create on-ground cells. The on-ground cells may be created through an on-ground relay node 104 or by a gNB located on-ground or in a satellite.

It is obvious for a person skilled in the art that the depicted system is only an example of a part of a radio access system and in practice, the system may comprise a plurality of (e/g)NodeBs, the user device may have an access to a plurality of radio cells and the system may comprise also other apparatuses, such as physical layer relay nodes or other network elements, etc. At least one of the (e/g)NodeBs or may be a Home(e/g)nodeB. Additionally, in a geographical area of a radio communication system a plurality of different kinds of radio cells as well as a plurality of radio cells may be provided. Radio cells may be macro cells (or umbrella cells) which are large cells, usually having a diameter of up to tens of kilometers, or smaller cells such as micro-, femto- or picocells. The (e/g)NodeBs of FIG. 1 may provide any kind of these cells. A cellular radio system may be implemented as a multilayer network including several kinds of cells. Typically, in multilayer networks, one access node provides one kind of a cell or cells, and thus a plurality of (e/g)NodeBs are required to provide such a network structure.

For fulfilling the need for improving the deployment and performance of communication systems, the concept of “plug-and-play” (e/g)NodeBs has been introduced. Typically, a network which is able to use “plug-and-play” (e/g)Node Bs, includes, in addition to Home (e/g)NodeBs (H(e/g)nodeBs), a home node B gateway, or HNB-GW (not shown in FIG. 1). A HNB Gateway (HNB-GW), which is typically installed within an operator's network may aggregate traffic from a large number of HNBs back to a core network.

One key element necessary in overcoming high path and penetration losses of millimeter wavelengths and thus achieving high throughput broadband communications envisioned for 5G NR communication systems like the one shown in FIG. 1 is the use of beamforming techniques. Beamforming techniques employ an array antenna comprising a plurality of antenna elements, for example, in a rectangular or square configuration. By tuning the phase and/or amplitude of the signals fed to each antenna element, different antenna patterns may be produced due to the electromagnetic waves produced by the individual antenna elements interfering with each other constructively and destructively in different directions. Due to reciprocity, the same principle applies equally in reception. In particular, the radiation pattern of the antenna array may be tuned so that a narrow main beam of the radiation pattern is directed to different directions (e.g., different directions defined through azimuth and/or elevation angles). In other words, the electromagnetic waves may be focused in a desired direction in transmission and/or the electromagnetic waves may be received only from a desired direction in reception. In addition to the direction of the main lobe, the sidelobe levels and the nulls of the pattern may also be controlled.

In 5G NR, the access node is configured to serve one or more cells so that each cell is mapped to a set of Synchronization Signal Block (SSB) beams forming a grid of beams covering the cell. For the 5G New Radio Release 15, the beam alignment procedure between the terminal device (UE) and the access node (gNB) consists of three main phases.

In the first phase, the terminal device is assumed to be configured for broad beam reception while the access node is performing downlink (DL) SSB beam sweeping. The terminal device measures reference signal received power (RSRP) for all received SSB beams and reports back to the access node using same beam configuration as in reception, by selecting the random-access resources (RACH Group) which corresponds to the best SSB beam measured by the terminal device. The random-access resources are determined based on the information decoded by the terminal device, Master Information Block (MIB) and System Information Block 1 and 2 (SIB1 & SIB2), in correspondence with the best SSB beam.

In the second phase, the terminal device is assumed to be configured for broad beam reception while the access node is performing refined DL channel state information reference signal (CSI-RS) beam sweeping. The terminal device measures RSRP (or channel quality indicator (CQI) and/or rank indicator (RI)) for all CSI-RS or SSB beams received and reports the best beam identifier (ID) back to the access node using same beam configuration as in reception.

In the third phase, the access node transmits with the best beam found in the second phase and the terminal device is sweeping refined reception beam settings for identifying the best narrow reception beam.

At the end of the third phase, alignment between the transmission beam of the access node and the reception beam of the terminal device is obtained for maximized directional gain and minimum interference on other users in serving and neighbor cells. It should be noted that the beam alignment procedure described above is based on downlink measurements only and, as a consequence, it cannot be guaranteed that the uplink beam of the terminal device will always be aligned with the access node, when configured with the same antenna array settings (phase and power) as used for downlink.

The uplink beam pair can be individually aligned by configuring the terminal device to transmit periodically SRS's when the uplink beam pair needs to the re-aligned. However, this is a very resource intensive procedure and, thus, not an ideal solution to the misalignment problem.

Beam correspondence might be true for the access node but cannot be guaranteed at the terminal device, as described above. Indeed, the freedom in designing antennas for access nodes is considerable compared to the freedom in designing antennas for terminal devices. Moreover, terminal devices have a large number of constraints such as supporting a very large bandwidth for enabling world-wide coverage. Further, terminal devices are oftentimes implemented with cheaper embedded components compared to access node which may lead to compromised tolerance levels and considerable impedance variations across different operational settings.

While careful design and characterization aims at securing uplink/downlink beam correspondence, there are more factors which may impact terminal device uplink/downlink beam correspondence dynamically. For example, the impedance of the individual antenna elements of an antenna array (i.e., the impedance as “seen” by the individual antenna elements) will undergo significant changes over frequency as the main beam of the antenna array is steered in different angular directions. This is mostly due to the relative high coupling between the individual antenna elements of the antenna array, which is a fundamental behavior of electrically small impedance broadband phase-controlled arrays used in 5G NR millimeter-wave devices. Power amplifiers (PA's) are especially sensitive to these changes in impedance. Since each antenna element in the antenna array is typically connected directly to a PA, each PA will behave differently which can result in an angular misalignment of the main beam for uplink, reduced PA efficiency, worse PA linearity and increased Spurious Emission.

The impact of impedance mismatch at the PA output port (i.e., in transmission) is significantly different to that on the low noise amplifier (LNA) input port (i.e., in reception), which in turn will affect the transmission and reception beam differently for the same load mismatch. In general, the transmission beam is expected to be more affected than the reception beam. Furthermore, if the transmission beam does not correspond to the reception beam, power is not optimally received at the access node.

The sensitivity of the antenna array to the beam non-correspondence depends on the size of the antenna array (i.e., the number of antenna elements in the antenna array). Indeed, a large antenna array corresponds, in general, to a narrow beam and increased sensitivity to misalignment with the beam of the access node. As such, the problem is aggravated as frequency increases due to the beams getting narrower (with the associated increased demand for high beam direction accuracy) for sustained link budget, eventually affecting throughput.

Moreover, the coupling between the individual antenna elements depends on the angular direction of the main beam. Namely, the relative phase difference between the individual antenna element feed ports (induced by phase shifters) is increased when the angular direction of the main radiation beam is steered away from the broadside direction and said relative phase difference will affect coupling between each antenna element feed port as a function of the required angular beam steering direction and thereby also affect the impedance seen by the individual power amplifiers (i.e., the effective antenna impedance or the antenna impedance after matching). Broadside direction is defined as a direction perpendicular to the axis or plane of the antenna array. To radiate perpendicularly, the antenna elements of the antenna array typically must be fed in phase. Broadside direction may be equal to a boresight direction of the antenna array when all of the antenna elements of the antenna array (or specifically, a broadside array) are fed in-phase (e.g., 0° phase shift is applied by all phase shifters associated with the antenna elements). In general, a boresight direction of an antenna is defined as the direction of maximum gain (maximum radiated power) of said antenna.

The coupling between the individual antenna element, and thus the impedance seen by the power amplifiers, is further affected by the configured MIMO rank (i.e., whether MIMO or SIMO is used). In SISO, only one RF beamforming branch is used at the RF Module, while the other RF beamforming branch is inactive (assuming a MIMO system with two RF beamforming branches in the RF module). The coupling between the antenna element feed ports on the antenna array depends, in this case, also on the state of the inactive RF beamforming branch (open, short, terminated or undefined). Terminated may be considered the preferred solution as this eliminates any possible reflection from those inactive element feed port. In MIMO, both RF beamforming branches are active and the coupling between the antenna element feed ports is defined by that state, which means that termination is not possible.

In addition to the impedance mismatch, the operation may be further deteriorated due to related misbehavior of the PA under load mismatch. This will affect the Tx path even more when facing a poorly matched impedance load. Some relevant PA impairments potentially arising from load mismatch are highlighted below:
Load-pulling, the output power capabilities of the PA's are affected by the load impedance seen by the PA. This will result in further reduction of the delivered output power, in addition to the power reduction caused by impedance mismatch reflection.
PA efficiency degradation, which will increase the current consumption and lead to increased heat dissipation.
PA linearity degradation, which will distort the transmitted signal leading to worse adjacent channel leakage ratio (ACLR) and error vector magnitude (EVM).
Spurious Emissions increase, which could make the device fail the regulatory requirement for spurious emission.

These undesired PA behaviors will also affect the risk and severity of downlink/uplink beam non-correspondence at the terminal device, i.e., the problem of the uplink beam of the terminal device not corresponding with the aligned downlink beam of the terminal device. In addition, the uplink signal quality and user experience will be degraded and in worst case fail regulatory requirements.

The embodiments to be discussed below in detail seek to overcome at least some of the problems relating to impedance mismatch outlined above.

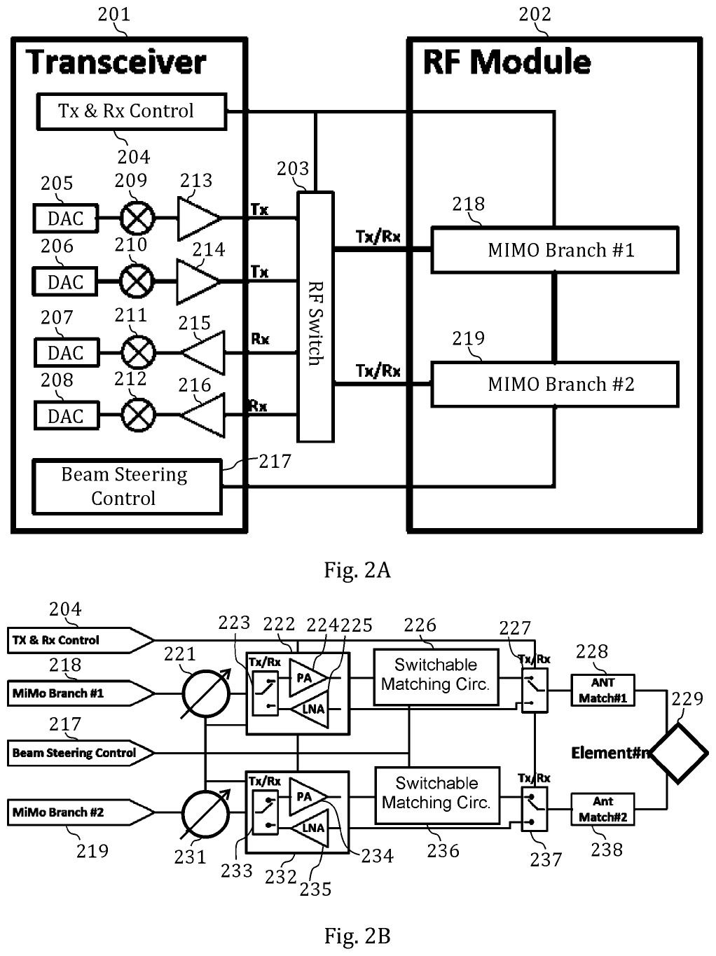

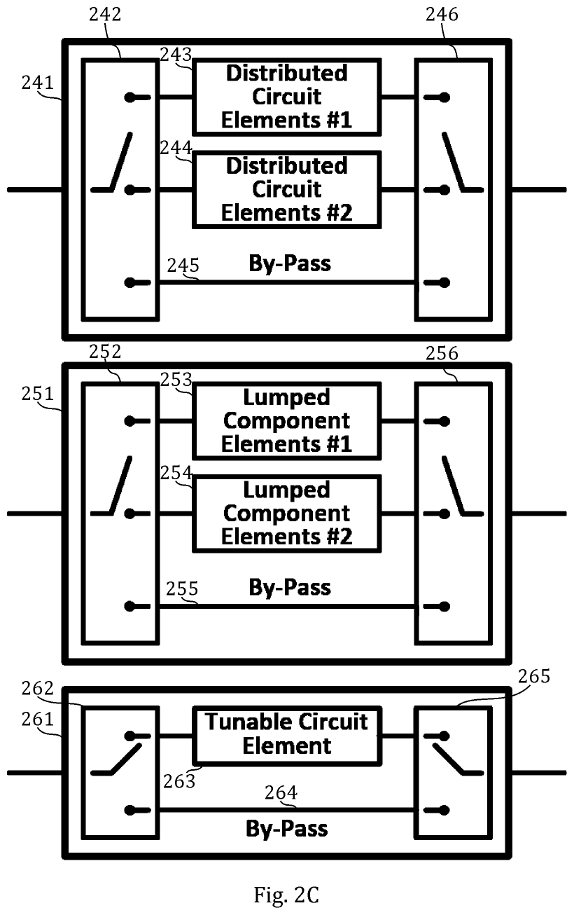

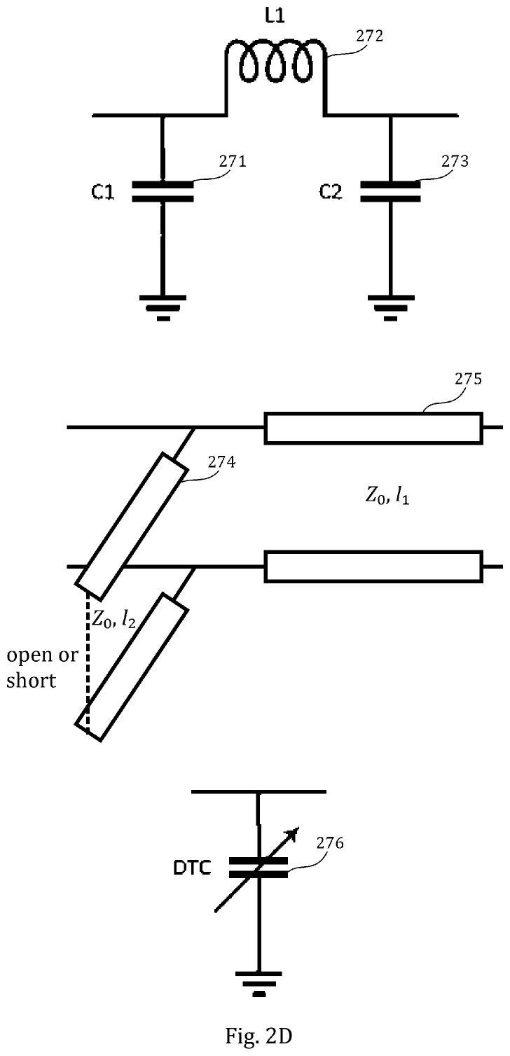

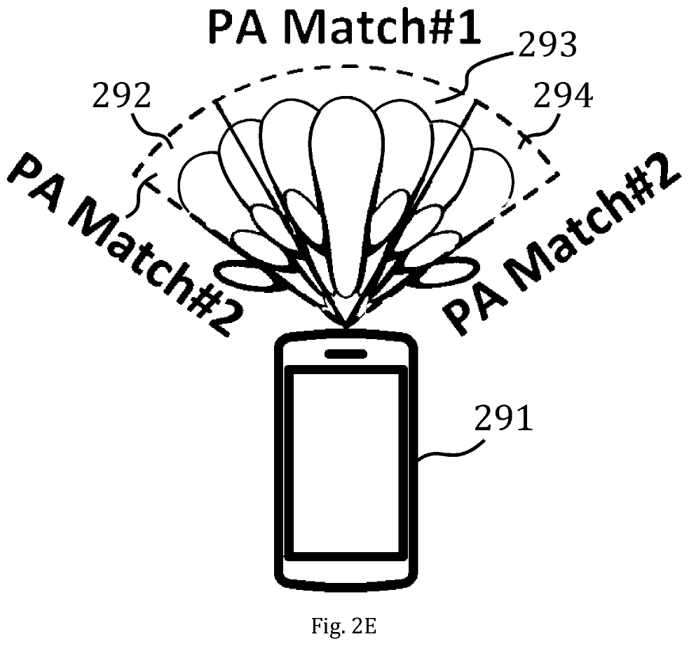

FIGS. 2A and 2B illustrate, respectively, a beamforming (or MIMO) transceiver architecture according to embodiments for transmitting and receiving data over a wireless communication network using multiple beams and a RF front end module 202 according to embodiments. The RF front end module of FIG. 2B may form a part of said beamforming transceiver architecture illustrated in FIG. 2A. The illustrated RF front end module 202 comprises RF elements relating to a single antenna element of the antenna array of the beamforming transceiver. The antenna array may be a one-dimensional antenna array (or a linear antenna array) or a two-dimensional antenna array. The antenna array may be specifically a broadside array providing maximum gain/directivity to a direction perpendicular (or broadside) to the axis or plane of the antenna array when the antenna elements of the antenna array are fed in-phase. In other words, the RF front end module 202 illustrated in FIG. 2B may be specifically a part of a complete RF front end for a beamforming transceiver (or a MIMO transceiver). The apparatuses illustrated in FIGS. 2A and/or 2B may be comprised in a terminal device such as any of the terminal devices 100, 102 of FIG. 1 or in an access node such as the access node 104 of FIG. 1.

Referring to FIG. 2A, the beamforming transceiver architecture comprises a baseband beamforming transceiver 201 and one or more RF front end modules 202 of which only one is illustrated in FIG. 2A (and in FIG. 2B). The baseband beamforming transceiver 201 is connected to the one or more RF front end modules via a RF switch 203. The RF switch is configured to enable electric switching, by a Tx & Rx control unit 204 (or equally Tx & Rx control means), for selecting which Tx RF signals are to be fed to which RF beamforming branches 218, 219 of which RF front end modules 202 and which RF signals received from RF beamforming branches 218, 219 of the one or more RF front end modules are to be fed to which Rx branches of the baseband beamforming transceiver 201.

The baseband beamforming transceiver 201 comprises, for enabling transmission, at least two or more digital-to-analog converters (DAC) 205, 206 for converting digital baseband signals to be transmitted to corresponding analog baseband signals, two or more Tx mixers 209, 210 for converting the analog baseband signals to corresponding RF signals and two or more Tx amplifiers 213, 214 for amplifying the RF signal received from a corresponding Tx mixer 209, 210. Moreover, the baseband beamforming transceiver 201 comprises, for enabling reception, two or more Rx amplifiers 215, 216 for amplifying the received RF signals before mixing, two or more Rx mixers 211, 212 for converting the received RF signals to corresponding analog baseband signal and two or more analog-todigital converters (ADC) 207, 208 for converting the analog baseband signals to corresponding digital baseband signals.

Moreover, the baseband beamforming transceiver 201 comprises a Tx & Rx control unit 204 for controlling whether the beamforming transceiver is currently in transmission or reception mode (e.g., by controlling the RF switch 203 and Tx/Rx switches of the one or more RF front end modules 202) and a beam steering control unit 217 (or equally beam steering control means) for controlling the beamforming functionalities (e.g., adjusting phase shifts applied in each RF beamforming branch for each antenna element). The Tx & Rx control unit 204 and the beam steering control unit 217 may be separate computing devices or comprised in a single computing device.

It should be emphasized that only some of the elements and functional entities of the baseband beamforming transceiver 201 are illustrated in FIG. 2A. It is apparent to a person skilled in the art that the system typically comprises also other functions and structures than those shown in FIG. 2A. For example, the baseband beamforming transceiver 201 may further comprise one or more digital baseband processing units for processing digital baseband signals before transmission and/or after reception, one or more local oscillators for providing a local oscillator signal for the mixers 209-212 for generating an analog baseband signal or a RF signal of a desired frequency and/or one or more analog and/or digital filters.

In some embodiments, the baseband transceiver employed in connection with a RF front end according to embodiments may also differ from the one illustrated in FIG. 2A in other ways. In general, the baseband beamforming transceiver 201 may comprise one or more digital and/or analog units as commonly found in MIMO-enabled or beamforming transceivers. Said one or more digital and/or analog units may be configured to perform, for example, digital/analog baseband processing, beam steering control, channel estimation, MIMO detection, precoding, spatial multiplexing and/or time- and/or frequency-scheduling.

Referring to FIGS. 2A and 2B, the illustrated RF front end architecture 202 comprises two RF beamforming branches 218, 219 for a single antenna element 229 of the antenna array of the beamforming transceiver. A RF beamforming branch 218, 219 may be equally called a MIMO branch (or a SIMO/MIMO branch in connection with some embodiments to be discussed below) or simply a RF branch. Each RF beamforming branch 218, 219 comprises a complete RF transceiver chain as illustrated with elements 221 to 228 or 231 to 238 for a particular antenna element 229 of the antenna array. Corresponding RF beamforming branches may be provided, in the beamforming transceiver, for each antenna element 229 of the antenna array (even though only the RF beamforming branches of a single antenna element is illustrated in FIGS. 2A and 2B). Thus, a set of corresponding RF beamforming branches 218, 219 for the plurality of antenna elements 229 (e.g., a set comprising all first RF beamforming branches 218 corresponding to the plurality of antenna elements) provides means for transmitting and receiving data signals using the whole antenna array and simultaneously with the transmission/reception occuring at other parallel RF beamforming branches 218, 219. Each set of corresponding RF beamforming branches 218, 219 feeding the plurality of antenna elements 229 may target at a time, for example, a specific cell or a specific user (if the beamforming transceiver corresponds to an access node) or a specific access node (if the beamforming transceiver corresponds to a terminal device). While only two RF beamforming branches 218, 219 are illustrated in FIG. 2B, in other embodiments, a larger number of RF beamforming branches may be provided.

Each RF beamforming branch 218, 219 comprises a RF transceiver chain comprising at least an electrically tunable phase shifting element 221, 231, a power amplifier (PA)/low-noise amplifier (LNA) module 222, 232, an electrically switchable matching circuit 226, 236, a second Tx/Rx switch 227, 237 and an antenna matching circuit 228, 238. The PA/LNA module 222, 232 comprises a first Tx/Rx switch 223, 233, a power amplifier 224, 234 (for transmission) and a low-noise amplifier 225, 235 (for reception).

The operation of each element in the RF transceiver chain is described in the following only for the first RF beamforming branch 218 for simplicity of notations. The definitions provided apply equally to the second RF beamforming branch 219 as well as to all the RF beamforming branches associated with the other antenna elements in the antenna array. Thus, elements 231 to 238 may be defined as described below for elements 221 to 228.

The electrically tunable phase shifting element 221 is configured to provide a phase shift for the RF signal so as implement a particular radiation pattern or beam for the antenna array. Said phase shift may be determined dynamically by a beam steering control network (to be discussed in relation to further embodiments). The electrically tunable phase shifting element 221 may be a phase shifter. As shown in FIG. 2B, the electrically tunable phase shifting element 221 is electrically connected to a pole of the first Tx/Rx switch 223.

The first and second Tx/Rx switches 223, 227 are used for switching (electronically) between transmitter and receiver operation. Specifically, each of the first and second Tx/Rx switches 223, 227 has a Tx position (the upper position in FIG. 2B) corresponding to a Tx port and a Rx position (the lower position in FIG. 2B) corresponding to a Rx port. The Tx ports of the first and second Tx/Rx switches 223, 237 define between them a Tx path of a RF beamforming branch 218 and Rx ports of the first and second Tx/Rx switches 223, 227 define between them a Rx path of the RF beamforming branch 218. The first and second Tx/Rx switches 223, 227 may be controlled by the Tx & Rx control unit 204.

In addition to the first Tx/Rx switch 223, the PA/LNA module 222 comprises a power amplifier 224 which is arranged in the Tx path of the RF beamforming branch and a low-noise amplifier 225 which arranged in the Rx path of the RF beamforming branch. The properties (e.g., at least gain) of the power amplifier and/or the low-noise amplifier 225 may be tunable by, e.g., Tx & Rx control unit 204 and/or a beam steering control unit 217 of the beamforming transceiver.

The antenna matching circuit 228 is configured to provide impedance matching for the antenna element 229. In other words, the antenna matching circuit provides impedance matching between an antenna impedance of the antenna element 229 and a characteristic impedance of a transmission line (e.g., a microstrip line) feeding the antenna element 229. In most applications, a characteristic impedance of 50Ω is used. The purpose of impedance matching is to enable efficient coupling of the signal to and from the antenna element 229. Specifically, the antenna matching circuit 228 may be configured to provide optimal impedance matching when a certain pre-defined beam steering is employed. This pre-defined beam steering angle may be specifically an angle corresponding to a broadside direction (usually defined as 0°). As described above, as the beam steering angle is changed, the impedance seen by the antenna element 229 (i.e., the effective antenna impedance) changes and thus the antenna matching circuit is no longer able to provide optimal impedance matching. This causes deterioration of the performance of the transceiver, especially in transmission, if no further impedance matching is provided.

While the Rx path of the RF beamforming branch (defined by the first and second Tx/Rx switches 223, 227) may comprise only the low-noise amplifier 225, the Tx path of the RF beamforming branch comprises, in addition to the power amplifier 224, an electrically switchable matching circuit 226 for addressing the impedance matching problem described above. The electrically switchable matching circuit 226 may follow the power amplifier 224 in the Tx path. Specifically, the electrically switchable matching circuit 226 may be electrically connected, in the Tx path, to the output port of the power amplifier 224 and the Tx port of the second Tx/Rx switch 227. The electrically switchable matching circuit 226 may be connected to the output port of the power amplifier 224 and the Tx port of the second Tx/Rx switch 227 directly (as illustrated in FIG. 2B) or via one or more circuits and/or one or more circuit elements. The electrically switchable matching circuit 226 comprises two or more matching circuit settings (e.g., two or more individual matching circuits) selectable via switching. The switching may be controlled by a beam steering control unit 217 which is also responsible for adjusting phase shifting at each RF beamforming branch 218, 219.

Each of the two or more matching circuits may be specifically configured for providing impedance matching for the antenna element 229 (that is, supplementary or additional impedance matching to the impedance matching provided by the antenna matching circuit 228) at one or more beam steering angles in transmission. In other words, each of the two or more matching circuit settings provides impedance matching between the characteristic impedance of the transmission line (e.g., 50Ω) and the impedance seen at the output of the electrically switchable matching circuit 226 (i.e., the effective antenna impedance after being impedance-matched with the antenna matching circuit 226). For example, one of the two or more matching circuit settings may correspond a broadside direction (i.e., a beam steering angle of 0°) while at least one of the two or more matching circuit settings may each correspond to different off-broadside directions (i.e., beam steering angles of ±a, where a is a positive angle smaller than or equal to 90°, preferably smaller than or equal to 50°). In other words, said one or more beam steering angles, for each of the two or more matching circuit settings, may correspond to a broadside angle of the antenna array or to two off-broadside angles defined symmetrically around the broadside angle. In practice, each of said one or more beam steering angles may correspond to a sector defined around the beam steering angle in question. The broadside angle is defined as angle relative to the broadside direction of the antenna array. The broadside angle may be equal to a boresight angle defined as an angle relative a boresight direction of the antenna array when all antenna elements of the antenna array are fed in-phase (e.g., 0° phase shift is applied by all phase shifters associated with the antenna elements).

In some embodiments, one of the two or more matching circuit settings (namely, the one corresponding to transmission to the broadside direction) may correspond to a by-pass circuit or line (i.e., to a single straight transmission-line segment) having no effect on the impedance matching. The antenna matching circuit 228 may be configured to provide optimal impedance matching specifically for the beam steering angle corresponding to said by-pass circuit. In other words, the antenna matching circuit 228 is configured to provide optimal matching at a particular pre-defined beam steering angle and consequently no additional impedance tuning is required for said pre-defined beam steering angle (even for transmission).

In some embodiments, the electrically switchable matching circuit 226 comprises a matching circuit setting selectable via switching corresponding to a matched termination (e.g., a 50Ω termination) for the antenna element 229. Such matching circuit setting in a RF beamforming branch enables optimal Tx SISO operation for the other RF beamforming branches (i.e., operation where only one of the RF beamforming branches 218, 219 is active) by preventing the RF signal from the active RF beamforming branch from coupling to and reflecting from the inactive RF beamforming branch. Obviously, such a matched termination may also be employed in the case of three or more Tx RF beamforming branches for using a lower MIMO rank in transmission (i.e., lower than what is possible with the beamforming transceiver architecture) by effectively deactivating one (or more) of the RF beamforming branches.

The two or more matching circuit settings may be defined in multiple different ways. Three examples of how the electrically switchable matching circuit 226, 236 may be implemented are illustrated in FIG. 2C. Each of the three illustrated electrically switchable matching circuits 241, 251, 261 may correspond to either of elements 226, 236.

According to a first alternative, each matching circuit setting may correspond to a separate matching circuit comprised in the electrically switchable matching circuit 226, 236. Thus, switching of the electrically switchable matching circuit 226, 236 corresponds to switching between different matching circuits. The top and middle electrically switchable matching circuits 241, 251 in FIG. 2C are examples of this type of electrically switchable matching circuit. In said top and middle electrically switchable matching circuits 241, 251, a pair of electrically controllable switches 242, 246, 252, 256 is used for selecting a matching circuit from three different alternatives 243 to 245, 253 to 255 (in general, two or more alternative matching circuits may be provided). In the top electrically switchable matching circuit 241, the first and second alternative matching circuits are matching circuits implemented with distributed circuit elements (corresponding to different beam steering angles, e.g. ±25° and ±50°) while the third matching circuit is a by-pass line 245. In the middle electrically switchable matching circuit 251, the first and second alternative matching circuits are matching circuits implemented with lumped circuit elements while the third matching circuit is a by-pass line 245. Implementation of the matching circuits using distributed/lumped elements is discussed in further detail in relation to FIG. 2D.

According to a second alternative, the electrically switchable matching circuit 226, 236 may comprise one or more (electrically controllable) tunable circuit elements (and optionally one or more non-tunable circuit elements) and each matching circuit setting may correspond to a tuning configuration of the one or more tunable circuit elements (e.g., changing the inductance of an inductor arranged in series or in parallel or a capacitance of a capacitor arranged in series or in parallel). The bottom electrically switchable matching circuit 261 of FIG. 2C corresponds to a slightly more advanced version of this idea in that, in addition to an electrically controllable tunable circuit element 263 (arranged in series or in parallel), a by-pass line 264 is provided. Switching between the tunable circuit element 263 and the by-pass line 264 may be provided via a pair of electrically controllable switches 262, 265 arranged on both sides of the tunable circuit element 263 and the by-pass line 264 (similar to the electrically switchable matching circuits 241, 251). Thus, two types of electric control are implemented in the case of the bottom electrically switchable matching circuit 261 of FIG. 2C: electric control for tuning the tunable circuit element 263 and electric control for operating the pair of switches 262, 265.

While not explicitly illustrated in FIG. 2C, a matched termination for a corresponding antenna element may, also or alternatively, be one of the switching options provided by any of the electrically switchable matching circuits 241, 251, 261 of FIG. 2C, in some embodiments.

Another alternative (not shown in FIG. 2C) is that each matching circuit setting corresponds to a switching configuration for one or more switchable circuit elements of the electrically switchable matching circuit. In other words, the switching of the electrically switchable matching circuit 226, 236 corresponds to switching a certain circuit element in the matching circuit topology of the electrically switchable matching circuit 226, 236 to another circuit element (e.g., a first capacitor to a second capacitor having a lower capacitance than the first capacitor).

The impedance matching, in the antenna matching circuit 228, 238 and in the electrically switchable matching circuits 226, 236 (specifically for each matching circuit setting defined therein), may be implemented using any conventional impedance matching circuitry for matching a complex (antenna) impedance to a transmission line (i.e., to a characteristic impedance of a transmission line which is usually 50Ω). Some examples of these alternatives are illustrated in FIG. 2D.

For example, each individual matching circuit of the antenna matching circuit 228 and the electrically switchable matching circuits 226, 236 may comprise one or more lumped (circuit) elements (so-called lumped element matching), as mentioned in connection with elements 243, 244 of FIG. 2C. Said one or more lumped circuit elements may comprise one or more capacitors arranged in series, one or more capacitors arranged in parallel (i.e., connected between the lines of the transmission line), one or more inductors arranged in series and/or one or more inductors arranged in parallel. The type and number of the used lumped circuit element and their order, connection type and values of inductance or capacitance depend on the (complex) impedance value to be matched. Multiple topologies (i.e., lumped element matching networks) may be used for matching the same impedance (the exact number of possible topologies being dependent on the value of the impedance to be matched). The top matching circuit of FIG. 2D corresponds to an example of a matching circuit implemented using lumped circuit elements. Specifically, said matching circuit comprises a first capacitor 271 in parallel, a first inductor 272 in series and a second capacitor 273 in parallel (in this order). The capacitance/inductance values of the elements 271, 272, 273 are selected so that optimal impedance tuning is achieved.

Additionally or alternatively, each individual matching circuit of the antenna matching circuits 228, 238 and the electrically switchable matching circuits 226, 236 may comprise one or more distributed circuit elements (so-called distributed element matching), as mentioned in connection with elements 253, 254 of FIG. 2C. Said one or more distributed circuit elements may comprise one or more transmission lines of a pre-defined length arranged in series, one or more open-ended transmission lines of a pre-defined length arranged in parallel (i.e., one or more open-ended stubs) and/or one or more short-circuited transmission lines of pre-defined length arranged in parallel (i.e., one or more lose-circuited stubs). Depending on the exact value of the complex impedance to be matched, different topologies of the matching circuit (i.e., different distributed element matching networks) are possible also in this case. The middle matching circuit of FIG. 2D corresponds to an example of a matching circuit implemented using distributed circuit elements. Specifically, said matching circuit comprises an open-ended or shorted stub 274 of length 12 and a transmission line segment 275 having a length h leading to an antenna element. All transmission lines in the example have the same characteristic impedance Zo (as is usually the case). By changing the lengths h and 12 and whether the stub is open-ended or shorted, impedance tuning achieved with the illustrated matching circuit may be adjusted.

Additionally or alternatively, each individual matching circuit of the antenna matching circuits 228, 238 and the electrically switchable matching circuit 226, 236 may comprise one or more tunable circuit elements (tunable distributed or lumped circuit elements), as mentioned in connection with element 263 of FIG. 2C. The one or more tunable circuit elements may comprise one or more tunable capacitors arranged in series and/or in parallel and/or one or more tunable inductors arranged in series and/or in parallel. The bottom matching circuit of FIG. 2D corresponds to an example of a matching circuit implemented using a tunable circuit element. Specifically, said bottom matching circuit of FIG. 2D comprises a digitally tuned capacitance (DTC) 276 arranged in parallel.

In some embodiments, at least one individual matching circuit of the antenna matching circuits 228, 238 and the electrically switchable matching circuits 226, 236 one or more matching circuits may be implemented using a combination of one or more lumped circuit elements, one or more distributed circuit elements and/or one or more tunable circuit elements.

In some embodiments, the antenna matching circuit(s) 228, 238 may be integrated into the antenna array.

It should be emphasized that only some of the elements of a RF front end associated with a single antenna element are illustrated in FIG. 2B (namely, only the elements relevant for the embodiments are illustrated). The RF front end may further comprise, for example, one or more RF filters.

FIG. 2E illustrates the operating principle of the RF front end architecture of FIG. 2B. In the illustrated example, the RF front end architecture in question is implemented in a terminal device 291. The antenna array of a terminal device typically covers at least an angular range of 90° (±45°) with 0° corresponding to a broadside direction. In FIG. 2E, an angular range of 100° (±50°) is used in order to include a small overlap. In the simplistic example illustrated in FIG. 2E, the electrically switchable matching circuit 226, 236 comprises at least two different matching circuit settings: a first matching circuit setting corresponding to a broadside direction illustrated with a first sector 243 and a second matching circuit setting corresponding to off-broadside directions illustrated with second and third sectors 292, 294. Additionally, the electrically switchable matching circuit 226, 236 may comprise a matched termination for SISO operation. In the illustrated example, the first sector 293 is associated with multiple individual beams employed by the terminal device 291 (i.e., by the transceiver therein) while each of the second and third sectors 292, 294 are associated with a single individual beam (i.e., the two beams with the highest positive and negative beam steering angles).

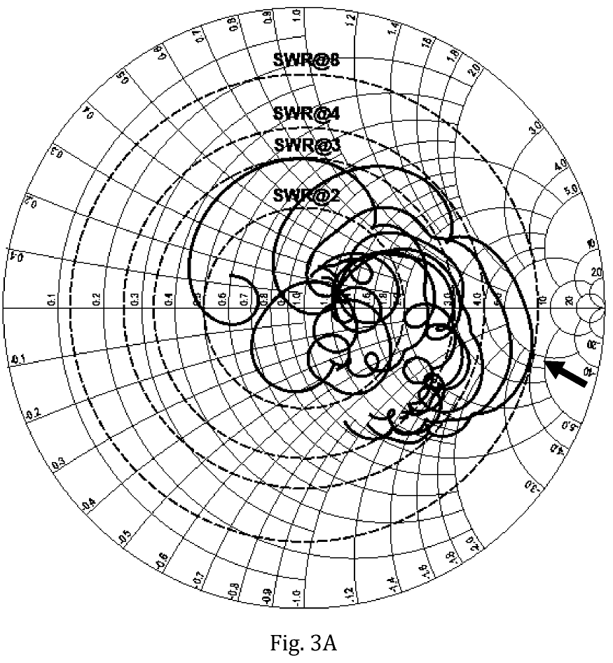

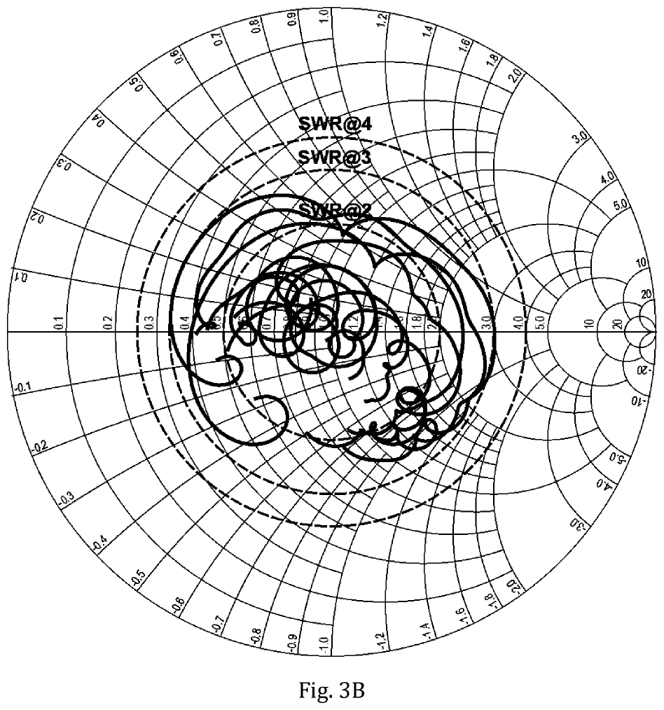

FIGS. 3A and 3B illustrates, using a pair of Smith charts, impedance matching without and with the electrically switchable matching circuit for a beam steering angle of 50° (i.e., 50° relative to the broadside direction), respectively. FIGS. 3A and 3B corresponds to a case where the antenna array is a 1×8 antenna array and to a frequency range of 24.25 GHz to 29.50 GHz. In other words, each separate line corresponds to impedance for a single antenna element in the frequency range of 24.25 GHz to 29.50 GHz. Which antenna element in the 1×8 antenna array line correspond to which line is irrelevant in view of the following discussion. A two-stage matching circuit switching approach is used in FIG. 3B, similar to as illustrated in FIG. 2E. The non-switchable antenna matching circuits are assumed to be optimized for impedance matching at broadside. FIGS. 3A and 3B correspond to results of full 3D electromagnetic simulations.

Smith chart is a tool for illustrating complex input impedances of loads normalized to the characteristic impedance of the transmission line in a convenient manner. The closer the input impedance is to the center of the Smith chart, the better the matching is (i.e., the smaller the reflection coefficient is). The Smith charts of FIGS. 3A and 3B also show four circles corresponding to different standing wave ratio (SWR) values (namely, to values 2, 3, 4 and 8). Standing wave ratio (or specifically voltage standing wave ratio) is another measure of impedance matching of loads to the characteristic impedance of a transmission line. Standing wave ratio is defined as the ratio of the partial standing wave's amplitude (voltage) at an antinode (maximum) to the amplitude at a node (minimum) along the line.

In FIG. 3A, no beam steering-dependent impedance matching is employed. Consequently, impedance matching is not optimal. At worst, a standing wave ratio of approximately 8 is observed (as highlighted with an arrow), that is, the plotted value are just barely within the SWR circle corresponding to the SWR value of 8. A SWR of 8 indicates very poor match impedance matching for a power amplifier. Such a poor value will result in severe unwanted behaviors (as described above) for the power amplifier facing such a high SWR.

In FIG. 3B, a two-stage beam steering-dependent impedance matching is employed. Consequently, the impedance matching is notably improved compared to the reference case of FIG. 3A. At worst, the standing wave ratio has a value of approximately 3, that is, the plotted values are roughly within the SWR circle corresponding to the SWR value of 3.

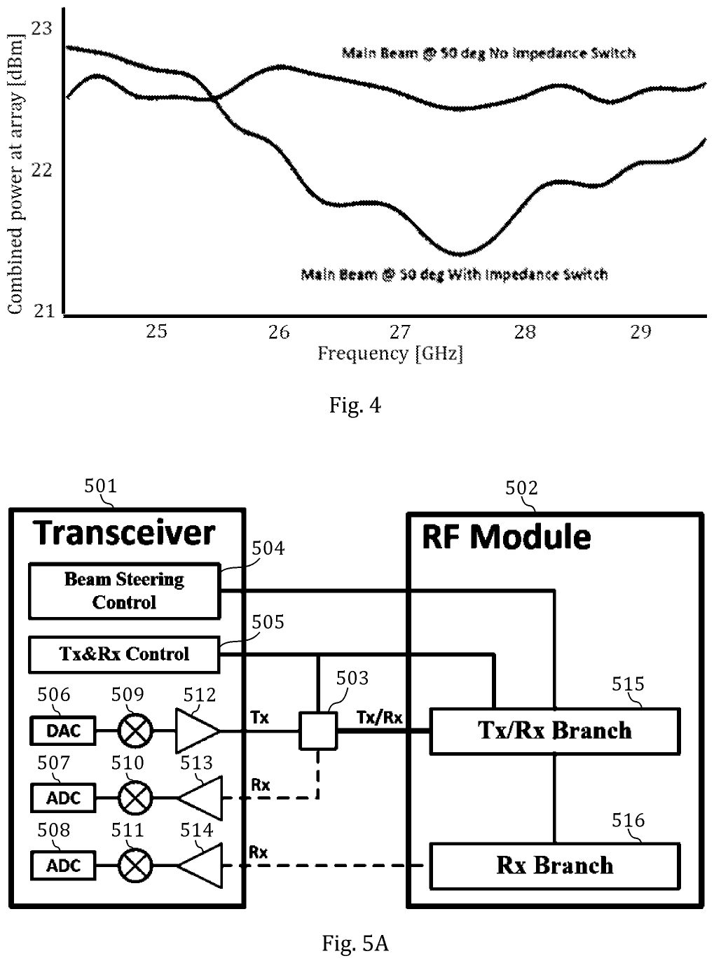

FIG. 4 illustrates combined power coupled to the plurality of antenna elements of the antenna array with and without the electrically switchable matching circuit for a beam steering angle of 50° (i.e., 50° relative to the broadside direction). The used beamforming transceiver and the antenna array are defined as described in relation to FIGS. 3A and 3B. The difference in combined power delivered to the antenna array when the switchable matching circuit is used and when it is not used is up to 1 dB. In addition and even more importantly, the effects of the improved power amplifier conditions (i.e., improved impedance match) cause a considerable increase in the quality of the transmitted RF signal. FIG. 4 shows results of simulations.

While FIGS. 2A and 2B illustrated, respectively, downlink/uplink MIMO transceiver and RF front end architectures, the same inventive concept may also be applied to downlink MIMO and uplink SISO transceivers and downlink MIMO and uplink SISO RF front end architectures (or equally to downlink SIMO and uplink MIMO transceiver and RF front end architectures). It should be noted that, for example, a 3GPP Release 15 compliant devices utilizing millimeter waves (Frequency Range 2, FR2) are required to support 2×2 MIMO for downlink but only SISO for uplink.

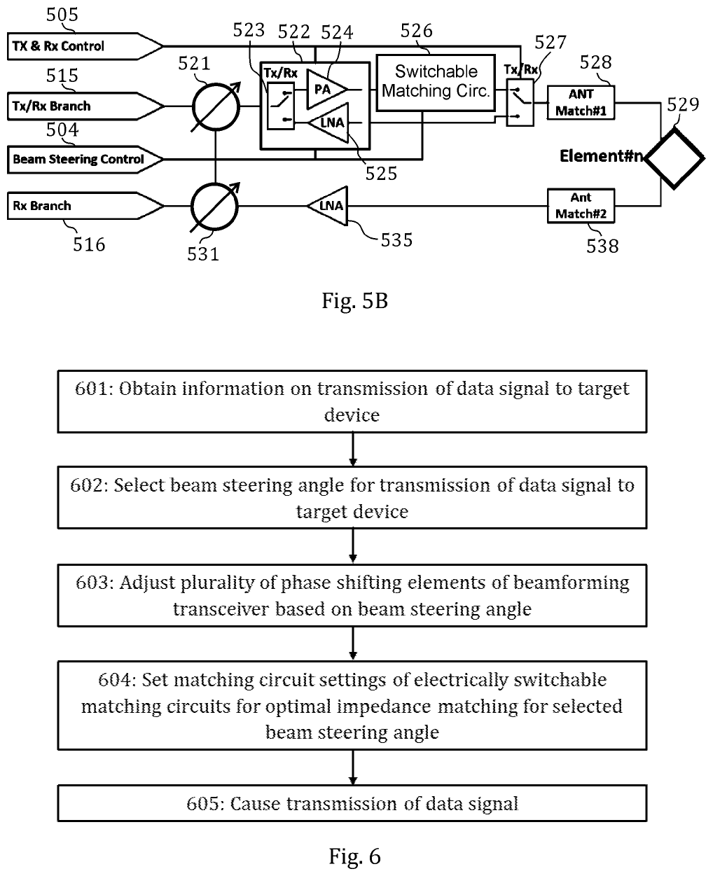

FIGS. 5A and 5B illustrate, respectively, an alternative beamforming transceiver architecture according to embodiments for transmitting and receiving data over a wireless communication network using multiple beams and a corresponding RF front end module 502 according to embodiments. The RF front end module of FIG. 5B may form a part of said beamforming transceiver architecture illustrated in FIG. 5A. The illustrated RF front end module 502 comprises RF elements relating to a single antenna element of the antenna array of the beamforming transceiver. In other words, the RF front end module 502 illustrated in FIG. 5B may be specifically a part of a complete RF front end for a beamforming transceiver. The apparatuses illustrated in FIGS. 5A and/or 5B may be comprised in a terminal device such as any of the terminal devices 100, 102 of FIG. 1 or in an access node such as the access node 104 of FIG. 1.

The apparatuses illustrated in FIGS. 5A and 5B correspond in many aspects to the apparatuses illustrated in FIGS. 2A and 2B. Therefore, said apparatuses are described in the following relatively briefly emphasizing the differences compared to the apparatuses of FIGS. 2A and 2B. Unless otherwise stated, definitions provided in connection with FIGS. 2A and 2B apply, mutatis mutandis, also to the embodiments illustrated in FIGS. 5A and 5B.

Similar to FIG. 2A, the beamforming transceiver architecture illustrated in FIG. 5A comprises a baseband beamforming transceiver 501 and one or more RF front end modules 502 of which only one is illustrated in FIG. 2A (and in FIG. 2B). The baseband beamforming transceiver 501 is connected to the one or more RF front end modules via a RF switch 503 for enabling electric switching, by a Tx & Rx control unit 505, for selecting when the Tx RF signals are to be fed to RF beamforming branches 515, 516 (one at a time) of which RF front end modules 502 and when the RF signals received from RF beamforming branches 515, 516 of the one or more RF front end modules are to be fed to the Rx branches of the baseband transceiver 201. As mentioned above, the beamforming transceiver illustrated with FIGS. 5A and 5B enables MIMO operation only in reception while in transmission only SIMO operation is possible.

The baseband beamforming transceiver 201 comprises, for enabling transmission, at least one or more digital-to-analog converters (DAC) 506 for converting digital baseband signals to be transmitted to corresponding analog baseband signals, one or more Tx mixers 509 for converting the analog baseband signals to corresponding RF signals and one or more Tx amplifiers 512 for amplifying the RF signal received from a corresponding Tx mixer 509, 510. Thus, in contrast to the beamforming transceiver of FIG. 2A, only one Tx branch needs to be provided in the baseband beamforming transceiver 501 according to the SIMO operation in transmission. The two branches of the baseband beamforming transceiver 501 defined by elements 507 to 514 may be defined as described for the two Rx branches of the baseband beamforming transceiver 201 of FIG. 2A. Also similar to the embodiments discussed in relation to FIGS. 2A and 2B, the baseband beamforming transceiver 501 further comprises at least a Tx & Rx control unit 504 and a beam steering control unit 516.

Referring to FIGS. 5A and 5B, the illustrated RF front end architecture 502, again similar to FIGS. 2A and 2B, comprises two RF beamforming branches 515, 516 for a single antenna element 529 of the antenna array of the beamforming transceiver. However, in this case only one 515 of the two RF beamforming branches 515, 516 comprises a complete RF transceiver chain (defined by elements 521 to 528). The other RF beamforming branch 516 comprises, in contrast, only a complete RF receiver chain (defined by elements 531, 535, 538). Corresponding RF beamforming branches may be provided, in the beamforming transceiver, for each antenna element 529 of the antenna array. While only one Tx/Rx RF beamforming branch 515 and only one Rx RF beamforming branch 516 is illustrated in FIGS. 5A and 5B, in other embodiments, a larger number of Tx/Rx and/or Rx RF beamforming branches (defined similar to the illustrated ones) may be provided.

The Tx/Rx RF beamforming branch 515 may be defined as described for the RF beamforming branches 218, 219 in connection with FIGS. 2B, 2C and 2D. It should be emphasized that, in contrast to FIGS. 2A and 2B, the Tx/Rx beamforming branch 515 cannot be strictly considered a “MIMO branch” as MIMO operation is provided with the beamforming transceiver of FIGS. 5A and 5B only in reception. Specifically, the electrically switchable matching circuit 526 may comprise, also in this case, two or more matching circuit settings (e.g., two or more individual matching circuits) selectable via switching, where each matching circuit setting corresponds to a particular beam steering angle.

The Rx RF beamforming branch 516 (equally called a Rx-only RF beamforming branch 516) comprises a RF receiver chain comprising at least an electrically tunable phase shifting element 531, low-noise amplifier (LNA) 535 and an antenna matching circuit 538. Said elements 531, 535, 538 may be defined as described in relation to corresponding elements 231, 235, 238 of FIG. 2B. The properties of the electrically tunable phase shifting element 531, the low-noise amplifier 535 and the antenna matching circuit 538 of the Rx RF beamforming branch 516 may or may not correspond to the properties of the corresponding elements 521, 525, 528 of the Tx/Rx RF beamforming branch 515.

In some embodiments, the implementation of the RF front end may differ from any of the ones discussed above (mainly in relation to FIGS. 2B and 5B). According to a more general embodiment, there is provided a RF front end for a beamforming transceiver having an antenna array comprising a plurality of antenna elements, where the RF front end comprises, for each of the plurality of antenna elements, at least two RF beamforming branches, each of at least one of said at least two RF beamforming branches comprising:

means for adjusting phase shifting in a RF beamforming path electronically (e.g., using beam steering control means);

means for switching between a Tx path (i.e., transmission operation) and a Rx path (i.e., reception operation) of the RF beamforming path (electronically, e.g., using Tx & Rx control means and/or beam steering control means);

means for signal amplification in the Rx path of the RF beamforming path;

means for signal amplification in the Tx path of the RF beamforming path; and

means for implementing impedance matching according to two or more electronically switchable matching circuit settings in the Tx path following the signal amplification in the Tx path, each of the two or more matching circuit settings being configured for providing impedance matching for the antenna element at one or more beam steering angles in transmission. The electronic switching between the two or more matching circuit settings may be controlled using beam steering control means.

For example, the means for adjusting may correspond a phase shifting element, the means for switching between the Tx and Rx paths may correspond to first and second Tx/Rx switches (e.g., elements 223, 227 of FIG. 2B), the means for the signal amplification in the Rx path may correspond to a low-noise amplifier (e.g., element 225 of FIG. 2B), the means for the signal amplification in the Tx path may correspond to a power amplifier (e.g., element 224 of FIG. 2B) and the means for implementing the impedance matching may correspond to an electrically switchable matching circuit (e.g., element 226 of FIG. 2B), where any of the definitions provided above for said exemplary elements may apply.

Additionally, each of at least one of said at least two RF beamforming branches may comprise, in some embodiments, means for implementing impedance matching between the antenna element and the RF beamforming branch both in transmission and reception. The means for implementing impedance matching may correspond to the antenna matching circuit (e.g., element 228 of FIG. 2B).

Any of the further features and properties discussed in connection with the specific embodiments (i.e., in relation to FIGS. 2A, 2B, 2C, 2D, 2E, 3A, 3B, 4, 5A and 5B) may be combined with the more general embodiments discussed above.

In summary, the RF front end architectures (for MIMO and SISO) according to embodiments discussed above provide at least the following advantages:
Reduction of beam non-correspondence scenarios.
Improved Tx output power over beam steering angle.
Improved PA linearity and efficiency stability over beam steering angle.
Improved performance in both MIMO and SISO configurations.
All improvements are obtained without added loss to the Rx paths.

FIG. 6 illustrates a process according to embodiments for performing beamforming (or beam steering) by a beamforming transceiver or specifically by beam steering control unit of the beamforming transceiver. The illustrated process may be carried out, for example, by the beamforming steering control unit 217 of FIGS. 2A and 2B or the beamforming steering control unit 504 of FIGS. 5A and 5B. In the following, the device carrying out the process is called simply an apparatus for brevity.

Initially, the apparatus obtains, in block 601, information on (upcoming) transmission of data signal to a target device (e.g., a terminal device or an access node). The type of the data signal or of the target device is irrelevant for the carrying out of this process. Said information may be obtained, for example, from another unit of the beamforming transceiver (e.g., from a Tx & Rx control unit or a digital baseband processing units for processing digital baseband signals). Specifically, said information may be obtained from beam alignment (entity) or beam management (entity) according to 5G NR 3GPP Release 15.

Then, the apparatus selects, in block 602, a beam steering angle to be used for said transmission based on the obtained information. In some embodiments, the beam steering angle may be explicitly included in said information or it may at least be derivable based on said information.

The apparatus adjusts, in block 603, phase shifts induced by a plurality of electrically tunable phase shifting elements (e.g., phase shifters) of the beamforming transceiver for forming a beam matching the beam steering angle (i.e., a beam directed towards the target device). Said adjusting of the phase shifts may be carried out using any conventional beamforming method, for example, based on a codebook table. The plurality of electrically tunable phase shifting elements may comprise, e.g., one of elements 221, 231 of FIG. 2B or element 512, 531 of FIG. 5B (and corresponding elements of other RF front end modules not shown in FIG. 2B or 5B).

The apparatus sets, in block 604, matching circuit settings of a plurality of electrically switchable matching circuits for optimizing the impedance matching in transmission for the selected beam steering angle. Again, the electrically switchable matching circuits may be defined as described above, e.g., in relation to elements 226, 236 of FIG. 2B, FIGS. 2C and 2D and/or elements 526 of FIG. 5B. Thus, each electrically switchable matching circuit may be arranged in a Tx path of a RF beamforming branch of a RF front end of the beamforming transceiver and may comprise two or more matching circuit settings selectable via switching. Each of the two or more matching circuit settings may be configured for providing impedance matching (or additional impedance matching in addition to a non-switchable matching circuit) for an antenna element at one or more beam steering angles in transmission (e.g., a broadside angle and one or more off-broadside angles). The electrically switchable matching circuit may also comprise a matching circuit setting corresponding to a matched termination. The apparatus may set (or activate), in each case in block 604, the matching circuit setting corresponding most closely to the beam steering angle. In some embodiments, each matching circuit setting may be associated with a sector (as in FIG. 2E) which defines which beam steering angles should trigger the use of which matching circuit setting.

Finally, the apparatus causes (or triggers), in block 605, transmitting of the data signal to the target device using the beamforming transceiver (or transmitter). The phase shifts of the plurality of electrically tunable phase shifting elements set in block 603 and the matching circuit settings of the plurality of electrically switchable matching circuits set in block 604 are employed in the transmitting.

In some embodiments, the apparatus may also adjust, in addition the phase shifting and the impedance matching, gain of a plurality of power amplifiers for amplifying the data signal to be transmitted. The plurality of power amplifiers may comprise, e.g., one of elements 224, 234 of FIG. 2B or element 524 of FIG. 5B (and corresponding elements of other RF front end modules not shown in FIG. 2B or 5B).

The blocks, related functions, and information exchanges described above by means of FIG. 6 are in no absolute chronological order, and some of them may be performed simultaneously or in an order differing from the given one. Other functions can also be executed between them or within them, and other information may be sent, and/or other rules applied. Some of the blocks or part of the blocks or one or more pieces of information can also be left out or replaced by a corresponding block or part of the block or one or more pieces of information.

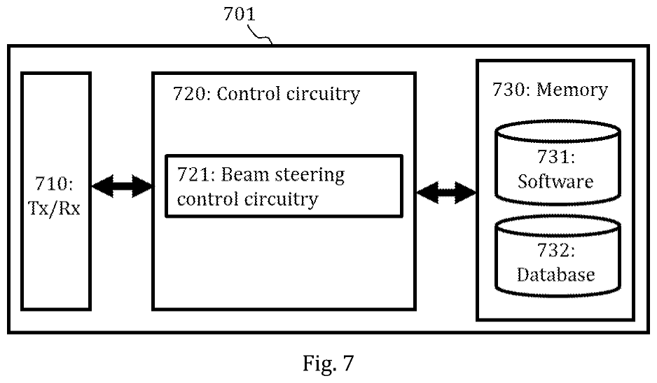

FIG. 7 provides an apparatus 701 (or a computing device) at least for performing beamforming. Specifically, the apparatus 701 may be a beam steering control unit of beamforming transceiver (or transmitter). The apparatus 701 may be a 5G apparatus. The apparatus 701 may be the beamforming steering control unit 217 of FIGS. 2A and 2B or the beamforming steering control unit 504 of FIGS. 5A and 5B. The apparatus 701 may be comprised in (i.e., form a part of) a terminal device or in an access node.

The apparatus 701 may comprise one or more control circuitry 720, such as at least one processor, and at least one memory 730, including one or more algorithms 731, such as a computer program code (software) wherein the at least one memory and the computer program code (software) are configured, with the at least one processor, to cause the apparatus to carry out any one of the exemplified functionalities of the apparatus (i.e., of the beam steering control unit) described above. Said at least one memory 730 may also comprise at least one database 732.

Referring to FIG. 7, the one or more communication control circuitry 720 comprise at least beam steering control circuitry 721 which is configured to perform beam steering (or beamforming) according to embodiments (in communication with RF elements of the RF front end of the beamforming transceiver). To this end, the encoding circuitry 721 is configured to carry out at least some of the functionalities described above by means of any of FIGS. 2A, 2B, 2C, 2D, 2E, 5A, 5B and 6 using one or more individual circuitries.

Referring to FIG. 7, the memory 730 may be implemented using any suitable data storage technology, such as semiconductor based memory devices, flash memory, magnetic memory devices and systems, optical memory devices and systems, fixed memory and removable memory.

Referring to FIG. 7, the apparatus 701 may further comprise different interfaces 710 such as one or more signaling interfaces (TX/RX) comprising hardware and/or software for realizing communication connectivity according to one or more communication protocols. Specifically, if the apparatus 701 corresponds to the beam steering control unit, the one or more signaling interfaces 710 may comprise, for example, interfaces providing a (wired) connection to a plurality of electrically tunable phase shifting elements, a plurality of electrically switchable matching circuits and one or more other units or elements of the beamforming transceiver (e.g., to one or more power amplifiers for controlling their gain). The one or more signaling interfaces 710 may, in some embodiments, provide the apparatus with communication capabilities to communicate in a cellular or wireless communication system, to access the Internet and a core network of a wireless communications network and/or to enable communication between user devices (terminal devices) and different network nodes or elements, for example.

The one or more signaling interfaces 710 may comprise standard well-known components such as an amplifier, filter, frequency-converter, (de)modulator, and encoder/decoder circuitries, controlled by the corresponding controlling units, and one or more antennas.

As used in this application, the term ‘circuitry’ may refer to one or more or all of the following: (a) hardware-only circuit implementations, such as implementations in only analog and/or digital circuitry, and (b) combinations of hardware circuits and software (and/or firmware), such as (as applicable): (i) a combination of analog and/or digital hardware circuit(s) with software/firmware and (ii) any portions of hardware processor(s) with software, including digital signal processor(s), software, and memory(ies) that work together to cause an apparatus, such as a terminal device or an access node, to perform various functions, and (c) hardware circuit(s) and processor(s), such as a microprocessor(s) or a portion of a microprocessor(s), that requires software (e.g. firmware) for operation, but the software may not be present when it is not needed for operation. This definition of ‘circuitry’ applies to all uses of this term in this application, including any claims. As a further example, as used in this application, the term ‘circuitry’ also covers an implementation of merely a hardware circuit or processor (or multiple processors) or a portion of a hardware circuit or processor and its (or their) accompanying software and/or firmware. The term ‘circuitry’ also covers, for example and if applicable to the particular claim element, a baseband integrated circuit for an access node or a terminal device or other computing or network device.

In an embodiment, at least some of the processes described in connection with FIGS. 2A, 2B, 2C, 2D, 2E, 5A, 5B and 6 may be carried out by an apparatus comprising corresponding means for carrying out at least some of the described processes. Some example means for carrying out the processes may include at least one of the following: detector, processor (including dual-core and multiple-core processors), digital signal processor, controller, receiver, transmitter, encoder, decoder, memory, RAM, ROM, software, firmware, display, user interface, display circuitry, user interface circuitry, user interface software, display software, circuit, antenna, antenna circuitry, and circuitry. In an embodiment, the at least one processor, the memory, and the computer program code form processing means or comprises one or more computer program code portions for carrying out one or more operations according to any one of the embodiments of FIGS. 2A, 2B, 2C, 2D, 2E, 5A, 5B and 6 or operations thereof.

Embodiments as described may also be carried out in the form of a computer process defined by a computer program or portions thereof. Embodiments of the methods described in connection with FIGS. 2A, 2B, 2C, 2D, 2E, 5A, 5B and 6 may be carried out by executing at least one portion of a computer program comprising corresponding instructions. The computer program may be provided as a computer readable medium comprising program instructions stored thereon or as a non-transitory computer readable medium comprising program instructions stored thereon. The computer program may be in source code form, object code form, or in some intermediate form, and it may be stored in some sort of carrier, which may be any entity or device capable of carrying the program. For example, the computer program may be stored on a computer program distribution medium readable by a computer or a processor. The computer program medium may be, for example but not limited to, a record medium, computer memory, read-only memory, electrical carrier signal, telecommunications signal, and software distribution package, for example. The computer program medium may be a non-transitory medium. Coding of software for carrying out the embodiments as shown and described is well within the scope of a person of ordinary skill in the art.

According to an embodiment, there is provided a computer program comprising instructions for causing an apparatus to perform the embodiments of the methods described in connection with FIGS. 2A, 2B, 2C, 2D, 2E, 5A, 5B and 6 (e.g., at least the method steps illustrated in FIG. 6 or at least some of them).

According to an embodiment, there is provided a computer readable medium comprising program instructions for causing an apparatus to perform the embodiments of the methods described in connection with FIGS. 2A, 2B, 2C, 2D, 2E, 5A, 5B and 6 (e.g., at least the method steps illustrated in FIG. 6 or at least some of them).

According to an embodiment, there is provided a non-transitory computer readable medium comprising program instructions for causing an apparatus to perform the embodiments of the methods described in connection with FIGS. 2A, 2B, 2C, 2D, 2E, 5A, 5B and 6 (e.g., at least the method steps illustrated in FIG. 6 or at least some of them). Even though the embodiments have been described above with reference to examples according to the accompanying drawings, it is clear that the embodiments are not restricted thereto but can be modified in several ways within the scope of the appended claims. Therefore, all words and expressions should be interpreted broadly and they are intended to illustrate, not to restrict, the embodiment. It will be obvious to a person skilled in the art that, as technology advances, the inventive concept can be implemented in various ways. Further, it is clear to a person skilled in the art that the described embodiments may, but are not required to, be combined with other embodiments in various ways.

1. (canceled)

2. The terminal device of claim 19, wherein the electrically switchable matching circuit comprises a matching circuit setting selectable via switching corresponding to a matched termination for the antenna element.

3. The terminal device of claim 19, wherein said one or more beam steering angles, for each of the two or more matching circuit settings, correspond to a broadside angle of the antenna array or to two off-broadside angles defined symmetrically around the broadside angle.

4. The terminal device according to claim 19, wherein each radio frequency beamforming branch associated with the plurality of antenna elements or each antenna element of the plurality of antenna elements comprises:
an antenna matching circuit for providing impedance matching between the antenna element and the radio frequency beamforming branch both in transmission and reception.

5. The terminal device of claim 4, wherein the antenna matching circuit is configured for providing optimal impedance matching for a pre-defined beam steering angle.

6. The terminal device of claim 5, wherein said pre-defined beam steering angle corresponds to a broadside angle of the antenna array.

7. The terminal device of claim 5, wherein one of the two or more matching circuit settings corresponds to said pre-defined beam steering angle, said one of the two or more matching circuit settings implementing a by-pass circuit providing no additional impedance matching.

8. The terminal device according to claim 19, wherein said at least two radio frequency beamforming branches comprise at least one reception-only radio frequency beamforming branch comprising, each, at least:
an electrically tunable phase shifting element; and
a low-noise amplifier.

9. The terminal device according to claim 8, wherein each of said at least one reception-only radio frequency beamforming branch further comprises an antenna matching circuit for providing impedance matching between the antenna element and a corresponding reception-only radio frequency beamforming branch.

10. The terminal device according to claim 19, wherein each of the two or more matching circuit settings corresponds to a separate matching circuit comprised in the electrically switchable matching circuit, to a tuning configuration of one or more tunable circuit elements of the electrically switchable matching circuit or to a switching configuration for one or more switchable circuit elements of the electrically switchable matching circuit.

11. The terminal device according to claim 19, wherein the electrically tunable phase shifting element and the electrically switchable matching circuit are configured to be controllable by a beam steering control unit of the beamforming transceiver.

12.-16. (canceled)

17. A method comprising:
obtaining information on upcoming transmission of a data signal to a target device;
selecting a beam steering angle to be used for said transmission based on the obtained information;
adjusting phase shifts induced by a plurality of phase shifting elements of the beamforming transceiver for forming a beam matching the beam steering angle;
setting matching circuit settings for a plurality of electrically switchable matching circuits for optimizing impedance matching in transmission for the beam steering angle, wherein each electrically switchable matching circuit is arranged in a transmission path of a radio frequency beamforming branch of a radio frequency front end of the beamforming transceiver and comprises two or more matching circuit settings selectable via switching, the two or more matching circuit settings being configured for providing impedance matching for an antenna element at two or more different beam steering angles in transmission; and
causing transmitting the data signal to the target device using the beamforming transceiver.

18. A non-transitory computer readable medium comprising program instructions that, when executed by an apparatus, cause the apparatus to perform at least the following:
obtaining information on upcoming transmission of a data signal to a target device;
selecting a beam steering angle to be used for said transmission based on the obtained information;
adjusting phase shifts induced by a plurality of phase shifting elements of the beamforming transceiver for forming a beam matching the beam steering angle;
setting matching circuit settings for a plurality of electrically switchable matching circuits for optimizing impedance matching in transmission for the beam steering angle, wherein each electrically switchable matching circuit is arranged in a transmission path of a radio frequency beamforming branch of a radio frequency front end of the beamforming transceiver and comprises two or more matching circuit settings selectable via switching, the two or more matching circuit settings being configured for providing impedance matching for an antenna element at two or more different beam steering angles in transmission; and
causing transmitting the data signal to the target device using the beamforming transceiver.

19. A terminal device comprising a beamforming transceiver comprising a radio frequency front end and an antenna array comprising a plurality of antenna elements, the radio frequency front end comprising, for each of the plurality of antenna elements, at least two radio frequency beamforming branches, each of at least one of said at least two radio frequency beamforming branches comprising:
an electrically tunable phase shifting element;
first and second transmission/reception switches, wherein each of the first and second transmission/reception switches has a transmission position corresponding to a transmission port and a reception position corresponding to a reception port, transmission ports of the first and second transmission/reception switches defining between them a transmission path of a radio frequency beamforming branch and reception ports of the first and second transmission/reception switches defining between them a reception path of the radio frequency beamforming branch;
a low-noise amplifier arranged in the reception path of the radio frequency beamforming branch;
a power amplifier arranged in the transmission path of the radio frequency beamforming branch; and
an electrically switchable matching circuit arranged in the transmission path of the radio frequency beamforming branch so as to follow the power amplifier, wherein the electrically switchable matching circuit comprises two or more matching circuit settings selectable via switching, each of the two or more matching circuit settings being configured for providing impedance matching for an antenna element at one or more beam steering angles in transmission.

20. The method of claim 17, wherein the electrically switchable matching circuit comprises a matching circuit setting selectable via switching corresponding to a matched termination for the antenna element.

21. The method of claim 17, wherein said one or more beam steering angles, for each of the two or more matching circuit settings, correspond to a broadside angle of the antenna array or to two off-broadside angles defined symmetrically around the broadside angle.

22. The method according to claim 17, wherein each radio frequency beamforming branch associated with the plurality of antenna elements or each antenna element of the plurality of antenna elements comprises:
an antenna matching circuit for providing impedance matching between the antenna element and the radio frequency beamforming branch both in transmission and reception.

23. The method of claim 22, wherein the antenna matching circuit is configured for providing optimal impedance matching for a pre-defined beam steering angle.

24. The method of claim 23, wherein said pre-defined beam steering angle corresponds to a broadside angle of the antenna array.

25. The method of claim 23, wherein one of the two or more matching circuit settings corresponds to said pre-defined beam steering angle, said one of the two or more matching circuit settings implementing a by-pass circuit providing no additional impedance matching.

26. The method according to claim 17, wherein said at least two radio frequency beamforming branches comprise at least one reception-only radio frequency beamforming branch comprising, each, at least:
an electrically tunable phase shifting element; and
a low-noise amplifier.
